(19) United States
(12) Patent Application Publication
(10) Pub. No.: US 2016/0254401 A1
(43) Pub. Date: Sep. 1, 2016

(54) ASSEMBLY OF PHOTO-VOLTAIC CELLS

(71) Applicant: STICHTING ENERGIEONDERZOEK CENTRUM NEDERLAND, Petten (NL)

(72) Inventors: Markus Johan JANSEN, Petten (NL); Johannes Adrianus Maria van ROOSMALEN, Petten (NL); Evert Eugène BENDE, Petten (NL); Anna Judith CARR, Petten (NL); Nicolas GUILLEVIN, Petten (NL); Benoit Jean Baptiste HEURTAULT, Petten (NL)

(21) Appl. No.: 15/029,788

(22) PCT Filed: Oct. 17, 2014
(86) PCT No.: PCT/NL2014/050724

§ 371 Date: Apr. 15, 2016

(30) Foreign Application Priority Data
Oct. 18, 2013 (NL) 2011647

(51) Int. Cl. H01L 31/044; H01L 31/05

(52) U.S. Cl. CPC H01L 31/044; H01L 31/0508; H01L 31/0516; H01L 31/18

(57) ABSTRACT

In an assembly of photo-voltaic cells, the cells are arranged in a matrix and connected in series. Bypass diodes are connected in parallel respective parts of the series connection. In each of these parts, the cells are arranged in a sub-matrix, for example of 4×4 cells. The matrix contains rows of sub-matrices that have identical first sub-matrix connection patterns, except at the edge of the matrix, where sub-matrices with a second sub-matrix connection pattern are used. Each first sub-matrix connection pattern extends over a plurality of rows of photo-voltaic cells of the matrix, running back and forth along successive columns through the plurality of rows. Each second sub-matrix connection patterns extends over a plurality of columns of photo-voltaic cells of the matrix, running back and forth along successive rows through the plurality of columns. The second sub-matrix connection patterns, connect first sub-matrix connection patterns at ends of pairs of the rows of first sub-matrix connection patterns.

### FIELD OF THE INVENTION

The invention relates to an assembly of photo-voltaic cells.

### BACKGROUND

U.S. 20120060895 discloses an assembly of photo-voltaic cells comprising a matrix of photo-voltaic cells that are connected in series to produce a sum of the output voltages of the individual cells at the terminals of the assembly. An assembly of photo-voltaic cells may be a solar energy collection module, further comprising a package and electrical connections. The series connection follows an alternating back and forth pattern through the matrix to facilitate connection of bypass diodes. In the back and forth pattern the series connection each time runs along a row perpendicularly inward from an edge of the matrix up to halfway along the row (through three cells), then to midway the next row and back to the edge through that next row, from there to the following row and inward again etc. At the last row of the matrix the series connection crosses over to the opposite edge and continues with similar back and forth patterns from that edge.

The bypass diodes are connected in parallel to groups of the cells. In U.S. 20120060895, such a group is formed by the series connected cells inward along a row in the back and forth pattern up to halfway along that row and back from cells halfway the next row. Bypass diodes are known per se in photo-voltaic cell assemblies. They compensate for the effect that shadowed cells act as sources with a negative voltage, associated with dissipation of energy. The bypass diode clips the voltage drop over its group of cells, rerouting the current around the group. The back and forth pattern of U.S. 20120060895 exposes connections to the cells at the start and end of the group at the edge of the matrix, where it is easy to provide the bypass diode.

However in U.S. 20120060895 the space used for the bypass diodes along the edges, and for the connection between opposite edges, may reduce the area available for energy collection. This problem would increase when the number of bypass diodes would be increased. Although bypass diodes counteract energy loss due to shadowing of the assembly as a whole, energy produced by any cell in a group will be lost when shadowing of part of the cells in the group causes forward bias of the bypass diode. Thus awkward shadows, which hit a few cells in many groups, say along the edge of the matrix, can still result in a disproportional reduction of energy production. This loss can be reduced by decreasing cell area in each group, i.e. by increasing the number of bypass diodes for a given area. But in the cell of U.S. 20120060895 this would reduce the area available for energy collection.

Preferably, a solar cell assembly is combined with a DC to AC conversion circuit configured to produce an AC line voltage (e.g. 220 Volt AC). Such a conversion circuit typically comprises a DC-DC converter followed by a DC-AC converter. The DC-DC converter compensates output voltage fluctuations, e.g. due to shadowing, line voltage fluctuations etc. The efficiency of the DC-DC converter can be optimized when the nominal DC voltage is substantially equal to the peak line voltage. Conversion circuits wherein the DC-AC converter performs compensation are also known. These are similarly more efficient for such DC voltages.

WO2010037393A1 discloses a solar cell assembly wherein DC-DC converters are used to increase the output voltage of the assembly. The solar cells are divided into sub-cells that are coupled in series. A DC-DC converter is connected to the series connection of a number of the sub-cells. A DC-DC converters serve to raise the DC output voltage of the assembly, to a level above standard line voltage (e.g. 220 Volt AC), to facilitate conversion to AC at that line voltage. Without DC-DC converters more than 500 sub-cells would be needed to realize the 310 Volts DC needed to realize such an AC voltage with optimal DC-DC conversion in the case of Si based solar sub-cells, which each produce about 0.5 Volt. The use of DC-DC converters for use with strongly different DC voltages raises cost and reduces average operational life-time of the assembly. Such use of high voltages well above 0.5 Volts may make it necessary to increase the distance between cells to provide sufficient electrical isolation. But increased distances lead to reduced light collection area and hence to less output power per unit area of solar modules.

### SUMMARY

Among others, it is an object to provide for an assembly of photo-voltaic cells, such as a solar energy collection module, wherein a high fraction of the area of the assembly is used for energy collection. An assembly of photo-voltaic cells is provided that comprises a matrix of photo-voltaic cells, an electrical connection structure providing a series connection of the cells, and bypass diodes connected in parallel respective parts of the series connection. Preferably all back contact photo-voltaic cells are used, i.e. cells with a back surface that contains contacts to base and emitter areas of the cell respectively. The electrical connection structure comprises rows of first sub-matrix connection patterns. Each of the first sub-matrix connection patterns provides the series connection within a sub-matrix of rows and columns of photo-voltaic cells. Each first sub-matrix connection pattern provides one of the respective parts of the series connection, extending over a plurality of rows of photo-voltaic cells of the matrix, running back and forth along successive columns through the plurality of rows. The first sub-matrix connection patterns at ends of a pair of the rows of first sub-matrix connection patterns are indirectly connected to each other. Rather than using a conductor to connect these first sub-matrix connection patterns, the connection is provided through second sub-matrix connection pattern that provide further ones of the respective parts of the series connection. Each of the second sub-matrix connection patterns provides the series connection within a sub-matrix of rows and columns of photo-voltaic cells. These second sub-matrix connection patterns extend over a plurality of columns of the matrix. This makes it possible to realize the connection between the rows of first sub-matrix connection patterns using assembly surface area that is used for photo-voltaic cells.

Each of the first and second sub-matrix connection patterns provides the series connection within a sub-matrix with rows and columns of photo-voltaic cells. Preferably the sub-matrix is rectangular or rectangular with beveled corners and more preferably square. The photo-voltaic cell at a first corner of the rectangular sub-matrix is at an end of the part of the series connection in the first or second sub-matrix connection pattern. These first corners of the first and second sub-matrix connection patterns at the end of the row lie adjacent to one another. The first and second sub-matrix connection patterns are electrically connected to each other at these first corners. In an embodiment, in the first sub-matrix connection pattern at the end of each row of the pair, the first corner lies away from the other row of the pair, that is, there is at least one row of photo-voltaic cells in the sub-matrix intermediate between the photo-voltaic cell at the first corner and the other row of first sub-matrix connection patterns. This results in a distance corresponding to a plurality of intermediate photo-voltaic cells between the cells at the first corners, which is bridged via the photo-voltaic cells that are connected by the second sub-matrix connection patterns. In an embodiment the photo-voltaic cells at the first corner and a second corner of the rectangular sub-matrix are at opposite ends of the part of the series connection in the sub-matrix connection pattern. These first and second corners are adjacent corners (i.e. not diagonally opposite). In the first sub-matrix connection patterns they lie in a same row of the matrix and in the second sub-matrix connection patterns the lie in a same column. The first sub-matrix connection patterns in the rows are electrically connected to each other at these first and second corners. The second sub-matrix connection patterns are electrically connected to each other at these second corners. Preferably, the rows of first sub-matrix connection in each pair are mirror images of each other. More preferably, the electrical connection structure comprises successive rows of connections that are alternately mirror images of each other.

In an embodiment the second corners of the first sub-matrix connection patterns at further ends of the rows in the pair, opposite the ends where the second sub-matrix connection patterns are located, are connected directly to adjacent first sub-matrix connection patterns in further rows of first sub-matrix connection patterns that are adjacent to rows in the pair.

In an embodiment, the first sub-matrix connection patterns at the ends of the pair of the rows each run back and forth through P rows, and the second sub-matrix connection patterns each run P times back and forth through the plurality of columns (that is, the number of time that the pattern runs forth plus the number of times that the pattern runs back equals P). In this way, the second sub-matrix connection patterns fit along the edge of the first sub-matrix connection pattern. If the shape of the photo-voltaic cells deviates substantially from a square shapes, the photo-voltaic cells connected by the second sub-matrix connection patterns may need to be arranged rotated by ninety degrees relative to those connected by the first sub-matrix connection patterns.

In an embodiment, the first sub-matrix connection patterns at the ends of the pair of the rows each run a second number Q times back and forth through said first number P of rows, and the second first sub-matrix connection patterns each run said first number P times back and forth through said second number Q of columns. Thus, the number of cells in each sub-matrix connection pattern is the same, which optimizes use of the bypass diodes.

In an embodiment P and Q are equal, i.e. sub-matrices of P×P cells are used. P may be four for example. Thus, substantially square sub-matrices are used, which makes the ratio between the maximum diameter of the sub-matrix and the number of cells in the sub-matrix small. This in turn reduces the number of sub-matrices that will generally be affected by the shadow of a given size.

In an embodiment, the bypass diodes are located at edges of the first and second sub-matrix connection patterns. This makes it possible to minimize the length of the conductors to the bypass diodes and hence resistive loss in the case of shadows.

In an embodiment, all photo-voltaic cells in the matrix have identical orientation (i.e. the direction between corresponding contact points is the same). This simplifies placement of the cells. In this embodiment the first sub-matrix connection pattern having identical layouts, the second sub-matrix connection pattern having layouts that differ from that of the first sub-matrix connection pattern. Thus, the layout compensates for the fact that the connections need to be different for the multi-column second sub-matrix connection patterns when the cells have the same orientation.

In an embodiment each of the first and second sub-matrix connection patterns comprises a first and second one of the photo-voltaic cells at the ends of the respective part of the series connection that is provided by the sub-matrix connection pattern, the first and second one of the photo-voltaic cells being located along a straight edge of the sub-matrix connection pattern, the electrical connection structure in the sub-matrix connection pattern comprising a pair of areas of electrically conducting material extending along said edge, electrically connected to contacts of the first and second one of the photo-voltaic cells respectively, the bypass diode that is connected in parallel with the photo-voltaic cells of the respective part of the series connection being located at said edge, electrically connected between the pair of areas. This minimizes the length of the conductors to the bypass diodes and hence resistive loss in the case of shadows.

In an embodiment, each of the first and second sub-matrix connection patterns comprises a first and second one of the photo-voltaic cells at the ends of the respective part of the series connection that is provided by the sub-matrix connection pattern, the electrical connection structure in the sub-matrix connection pattern comprising a first and second areas of electrically conducting material, electrically connected to contacts of the first and second one of the photo-voltaic cells respectively, the bypass diode that is connected in parallel with the photo-voltaic cells of the respective part of the series connection being located between a further contact of the first one of the photo-voltaic cells and the second area of electrically conducting material. This makes simplifies manufacture by making positioning of the diodes less critical.

According to another aspect method of manufacturing an assembly of photo-voltaic cells is provided, the method comprising
providing an electrical connection structure that provides for a series connection of the photo-voltaic cells,
providing bypass diodes on said electrical connection structure, each bypass diode for connection in parallel with the photo-voltaic cells of a respective part of the series connection;
arranging the photo-voltaic cells in a matrix with rows and columns of photo-voltaic cells;
establishing electrical contact between contacts of the photovoltaic cells and the electrical connection structure, wherein the electrical connection structure comprises
rows of first sub-matrix connection patterns, each first sub-matrix connection pattern providing one of the respective parts of the series connection, extending over a plurality of rows of photo-voltaic cells of the matrix, running back and forth along successive columns through the plurality of rows;
second sub-matrix connection patterns, connecting the first sub-matrix connection patterns at ends of a pair of the rows of first sub-matrix connection patterns, each second sub-matrix connection pattern providing a further one of the respective parts of the series connection, extending over a plurality of columns of photo-voltaic cells of the matrix, running back and forth along successive rows through the plurality of columns.

In an embodiment, photo-voltaic cells cut from wafers in said step of arranging the photo-voltaic cells are used in the matrix with rows and columns of photo-voltaic cells. By using cells that are smaller than wafers, it is made possible to used bypass diodes for groups of cells that occupy less area. Thus, shadowing will have less effect.

In an embodiment according to any one of the claims the number of cells in the matrix is at least 500, so that the nominal voltage output is at least 310 V DC for conversion to 220V AC. In an embodiment according to any one of the claims the assembly comprises a DC to DC down-converter, connected to the terminals of the series connection of the cells in the matrix. In an embodiment according to any one of the claims the assembly comprises a DC to AC down-converter, connected to the terminals of the series connection of the cells in the matrix.

In an embodiment according to any one of the claims the interconnection material that interconnects the cells in series is a conductive foil. Preferably a flat diode is used, i.e. a diode having opposite surface areas, wherein the distance between the surface areas is smaller than the minimum diameter of the surface areas, cathode and anode connections of the diode being located on opposite ones of the surface areas. Any type of diode may be used. In an embodiment the bypass diode is a piece of a cell of a same structure as the cells in the matrix, sandwiched in between the cell and the foil.

In an embodiment according to any one of the claims the terminals of the series connection of cells are located adjacent two opposite sides of the matrix.

### BRIEF DESCRIPTION OF THE DRAWING

These and other objects and advantageous aspects will become apparent from a description of exemplary embodiments with reference to the following figures.

FIG. 1 shows a matrix of photo-voltaic cells

FIG. 2 shows a cross-section through an assembly of photo-voltaic cells

FIG. 3a shows a layout of a connection pattern in a sub-matrix

FIG. 3b shows a schematic connection pattern in a sub-matrix

FIG. 4 shows sub-matrices that divide a matrix

FIG. 5a shows a schematic connection pattern in a sub-matrix

FIG. 5b shows a layout of a connection pattern in a sub-matrix

FIG. 6 shows connection of a bypass diode

FIG. 7, 7a illustrate use of sub-matrix with non-rectangular cells

### DETAILED DESCRIPTION OF EXEMPLARY EMBODIMENTS

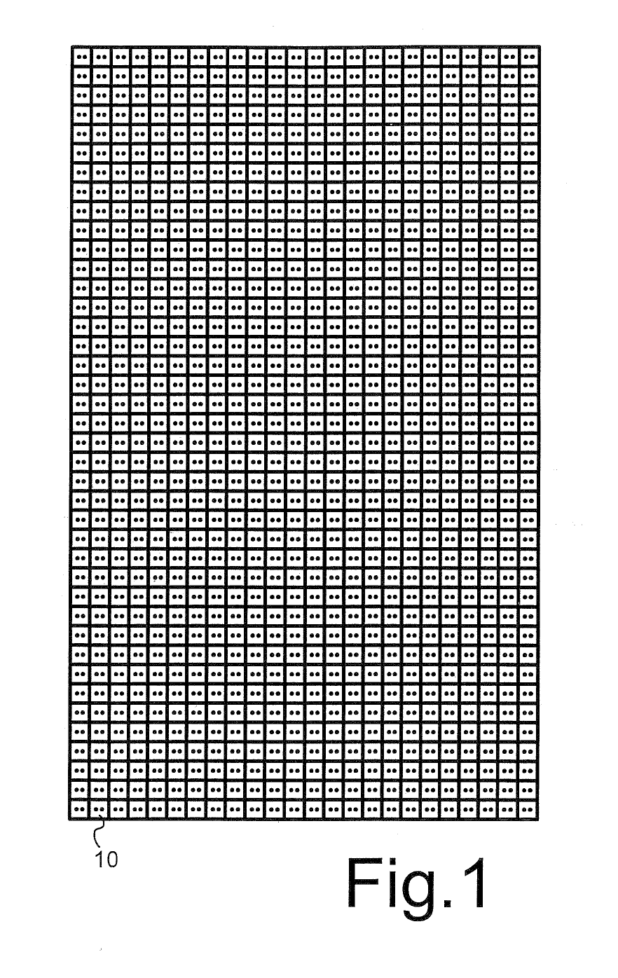

FIG. 1 symbolically shows photo-voltaic cells in a matrix with N rows and M columns of photo-voltaic cells 10 (only one labeled). By way of example a matrix of N=24 and M=40 rows and columns is shown, giving a total of N×M=960 cells. The matrix is part of a photo-voltaic energy collection module with electrical output terminals 12a,b. Electrically, the cells are connected in series between terminals 12a,b. Si based cells may be used, which produce a DC voltage output of about 0.5-0.6 Volts, so that a total output voltage of about 480 Volts between the terminals can be realized. In addition one or more DC-DC converters may be used to convert the DC voltage of the string to the desired output voltage. Preferably, the voltage is at least about 155 or 310 Volts for conversion to 220V AC and in an embodiment at least about 270 or 540 Volts, for three phase conversion. In this case no up-conversion is needed for DC to AC conversion at 220(110)

Volt and 380(190) Volt respectively, which simplifies the electronic circuit design, saves cost and yields a higher efficiency. Preferably, different embodiments of the matrix have at least five hundred cells, two hundred fifty cells, nine hundred cells and four hundred fifty cells respectively. Some excess cells may be advantageous to allow for compensation of temperature effects, variation in line voltage, shading etc.

The matrix is part of a photo-voltaic cell assembly, which may comprise a casing of the matrix with a window for exposing the cells to external light and electrodes coupled to the matrix. As may be noted electrical output terminals 12a,b are located adjacent rows on opposite sides of the columns, the columns being longer than the rows. In this way, the distance between the terminals is maximized, which reduces high voltage protection requirements In an embodiment, a photovoltaic cell assembly comprises an electronic DC to DC down converter (not shown) coupled to the terminals.

For each photo-voltaic cell, contacts on the cell for electrical connections to the cell have been indicated symbolically as a pair of dots. By way of example, the contacts within a cell may be offset relative to each other in the column direction. Preferably, the contacts are located near the centre of the surface of the cell, so as to minimize resistance between the contact and the edges of the surface. All photo-voltaic cells in the matrix have the same orientation, in the sense that the offset direction between the contacts is the same within each cell in the matrix.

Preferably all back contact cells are used, i.e. cells with a back surface that contains contacts to base and emitter areas of the cell respectively. In an embodiment, the photo-voltaic cells 10 may be metal wrap through cells, i.e. cells wherein a front surface electrode is connected to a first contact electrode on the back surface of the cell via a hole through the cell, and a second contact on the back surface connects to (or forms part of) a back surface electrode that covers the remainder of the back surface of the cell. Alternatively, other types of cell may be used, for example, cells that have interdigitated base and emitter electrodes on the back surface, connected to a first and second contact on the back surface respectively. The contacts may be part of bus bars that connect to the interdigitated base and emitter electrodes. In an embodiment, the photo-voltaic cells 10 may be cells obtained by cutting a wafer into identical dices. In another embodiment, cells with front and back contacts may be used, with contacts to base and emitter areas on opposite surfaces of the cell respectively. In this embodiment a conductive tab (e.g. a flexible strip of electrically conductive material) may be used for each cell, running from a front contact of the cell to its edge and from there through a space between adjacent cells to a contact to the foil underneath the back surface of the cell or a neighboring cell. However, use of all back contact cells is preferred.

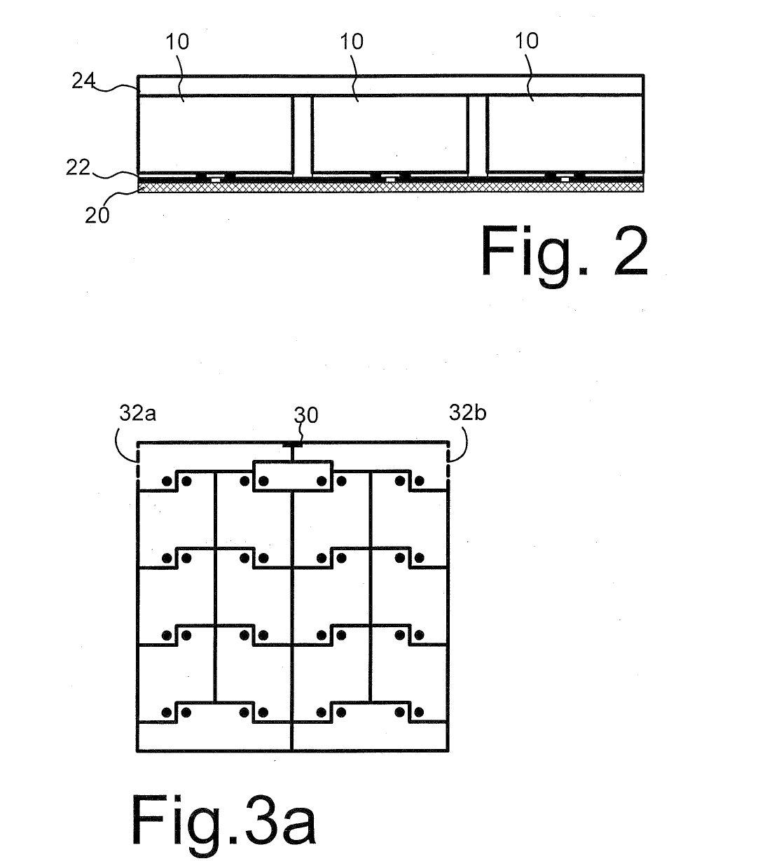

FIG. 2 shows a partial cross-section through an assembly of photo-voltaic cells that comprises the matrix (not to scale). The assembly comprises photo-voltaic cells 10 of the matrix, an electrically insulating, flexible foil 20 and areas of electrically conductive material 22 (e.g. copper) on foil 20, electrically connected to the contacts of the photo-voltaic cells 10. The electrically conductive material 22 on foil 20 are mutually isolated. Photo-voltaic cells 10 may be mounted with their front surfaces on a transparent plate 24. Photo-voltaic cells 10 may each comprise a layer of electrically insulating encapsulant on their back surface, with openings that define the contacts to the photo-voltaic cells 10. Connection material such as a solder or a conductive adhesive may be present in the openings to connect to the areas of electrically conductive material 22.

The connection pattern provided by foil 20 may be defined by distinguishing P×P sub-matrices of photo-voltaic cells 10 (P=4 by way of example), so that the matrix of FIG. 1 is also a matrix of N/P rows and M/P columns of these sub-matrices.

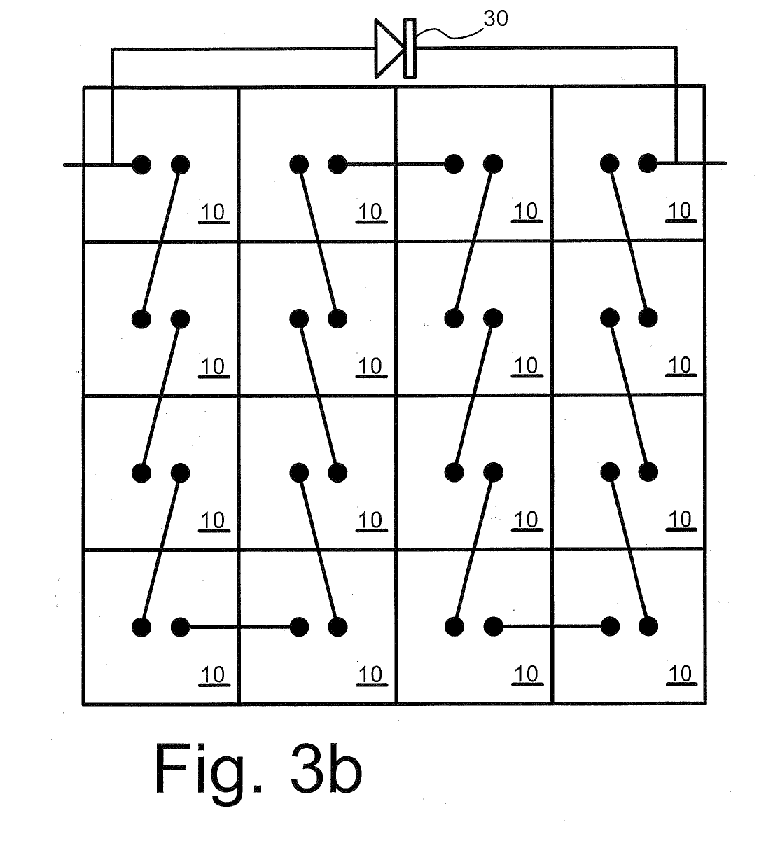

FIG. 3a shows a layout of the areas of the electrically conductive material on a part of the foil within a sub-matrix, which is used in all sub-matrices except for sub-matrices in a column of sub-matrices at the edge of the matrix. The inner lines indicate separations between different areas and the circles indicate holes for contact with the cells. Dashed lines 32a,b of the circumference indicates where the areas may extend to other parts of the foil that contain adjacent sub-matrices. The upper left and right areas run over into areas in columns to the left and right at dashed lines 32a b respectively. In addition FIG. 3a a bypass diode 30, which may be located on a pair of adjacent areas of electrically conductive material the foil.

FIG. 3b shows cells 10 in the sub-matrix and a schematic connection pattern realized by the areas of the electrically conductive material of FIG. 3a. The P×P cells of the sub-matrix are connected in series by a plough furrow pattern, which goes down for P cells along a column, then to the next column, then up P cells in that column, then to the next column and so on until all P columns have been visited. In addition FIG. 3b shows the connection of bypass diode 30, which is connected to bypass the cells in the sub-matrix. As can be seen the bypass diode 30 bypasses P columns, with P greater than two (P=4 in the example of FIGS. 3a,b). The sub-matrix substantially forms a square. In this way the maximum distance between cells that are bypassed by the same bypass diode 30 is minimized. This helps to minimize the effect of common shapes of shadow. In the example square cells are used arranged in the sub-matrix in as many columns as rows. When rectangular cells of width W and height H are used, a P×Q sub-matrix may be used, with a number of columns P unequal to the number of rows Q, but with a smaller difference between P*W and Q*H than between P*H and P*W.

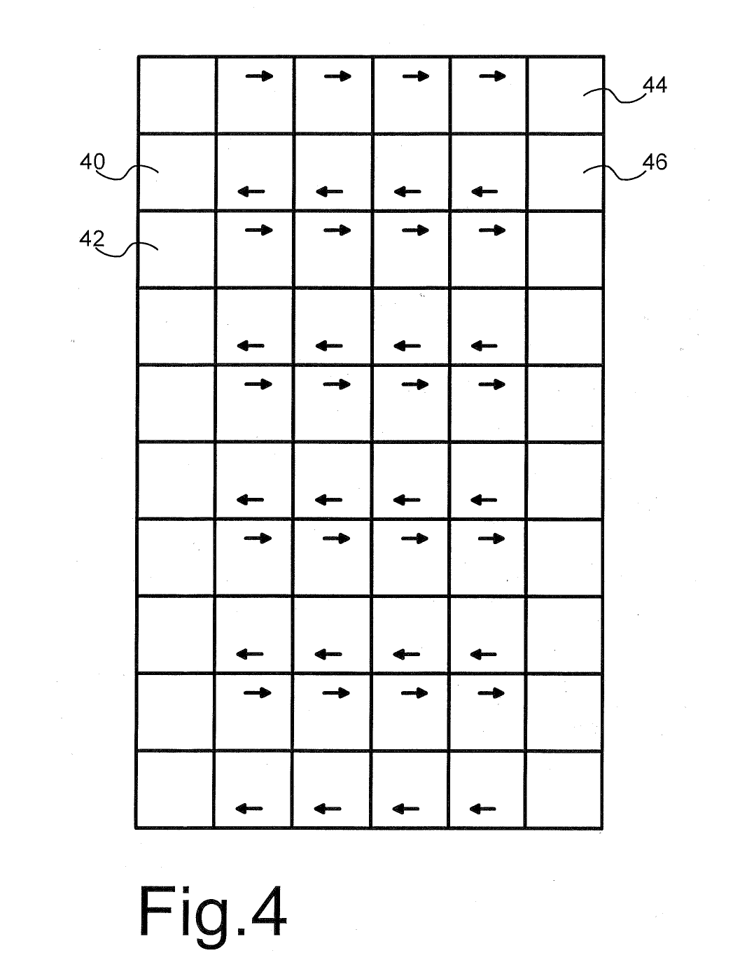

FIG. 4 shows the matrix of FIG. 1 divided into N/P rows and M/P columns of sub-matrices (N/P=6, M/P=10). The odd rows contain sub-matrices with layout as shown in FIG. 3a (indicated by arrows to the right). The even rows contain sub-matrices with layout as shown in FIG. 3a but rotated by 180 degrees (indicated by arrows to the left).

The layout in the sub-matrices 40, 42 (only two labeled) at the leftmost column may be very similar to those in the other columns except that the final (lower left) area of electrical conductor material in the leftmost sub-matrices 40 in the even rows run on into the first (upper left) area of electrical conductor material in the leftmost sub-matrix 42 in the next lower odd row. Thus, there is a direct connection between a cell in one sub-matrix with the layout of FIG. 3a to the next cell in the next lower sub-matrix with the layout of FIG. 3a.

At the right of the matrix, there is no such direct connection. Instead, each time a detour through P cells along the right edge of the overall matrix is used. Two types of sub-matrices 44, 46 (only two labeled) with P×P cells in even and odd rows of sub-matrices along the right edge can be distinguished, using a different layout compared to the sub-matrices to the left of the rightmost column, although the orientation of the cells in this column is the same as in the remainder of the matrix.

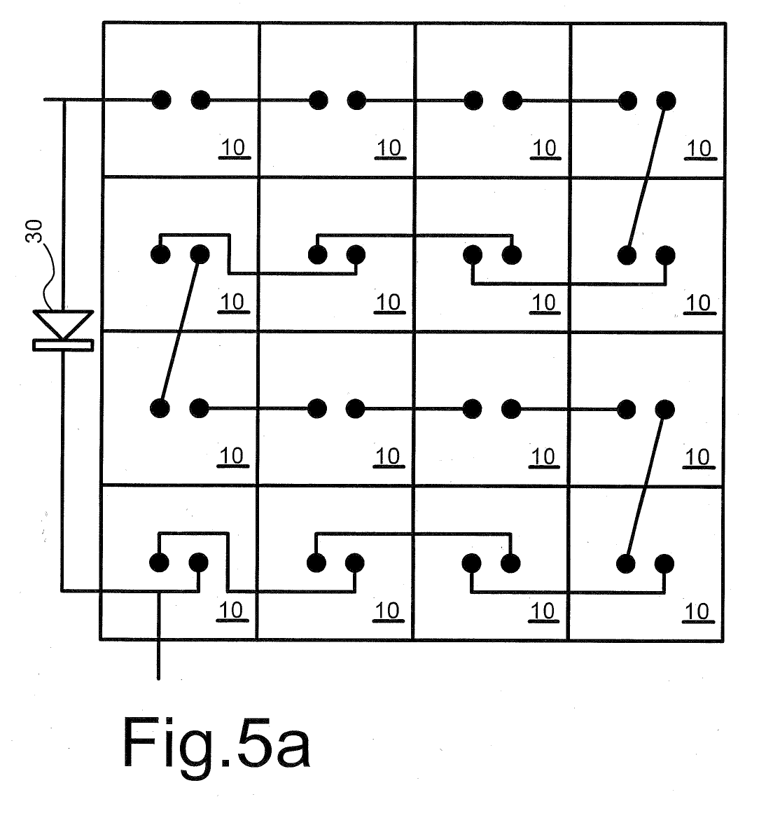

FIG. 5a shows P×P cells 10 in a sub-matrix in an odd row of sub-matrices at the rightmost column and a schematic connection pattern of the P×P cells realized by the areas of the electrically conductive material in that sub-matrix. The location of the contacts to the cells in this sub-matrix is the same as that in the other sub-matrices, because the orientation of all cells in the overall matrix is the same. However, the connection pattern differs. Roughly speaking, the P×P cells are connected in series by a plough furrow pattern, which goes right for P cells along a row, then to the next row, then left P cells in that row, then to the next row and so on until all P row have been visited. However, in the even rows, where the series connections are to the left, an “Echternach” series connection is used, which each time starts from a contact one step back (to the right) from the previous contact in the series connection, and steps over the next two contacts to the left to connect to the third contact.

FIG. 5b shows a layout of the areas of the electrically conductive material on a part of the foil within a sub-matrix that provides the connection pattern of FIG. 5a. Again dashed lines 50a,b show where areas run over into areas of an adjacent sub-matrix. The upper left area runs over into the column to the left and the lower left area runs over into the next lower row.

Substantially similar layout and connection patterns are used for the sub-matrices in the even rows of sub-matrices at the rightmost column, except that the upper left area runs over into the next higher row and the lower left area runs over into the column to the left.

The bypass diodes 30 of the sub-matrices in the rightmost columns each bypass the cells in their respective sub-matrix. In the illustrated example, the bypass diodes each bypass cells in a substantially square sub-matrix of P×P cells 10.

As will be appreciated, the connections in the sub-matrices in the rightmost columns ensure that similarly sized connection areas can be used everywhere in the matrix. By using special connections in P columns along the right edge of the matrix, the connection between successive rows of sub-matrices can be realized through a region that is occupied by photo-voltaic cells 10. Use of exceptionally long connection areas between successive rows of sub-matrices is not needed.

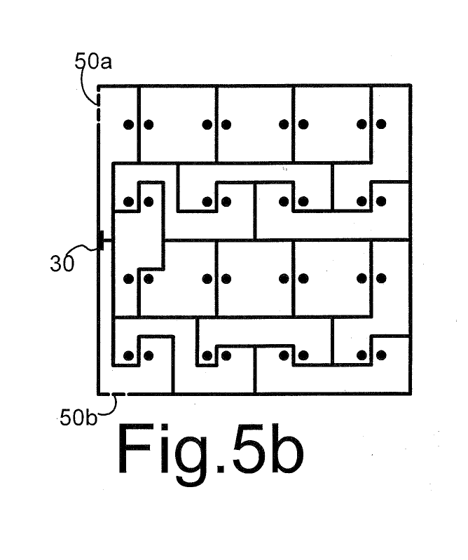

FIG. 6 illustrates the principle an embodiment wherein bypass diodes 60 are located between photo-voltaic cells 10a,b and foil 20. By way of illustration, the contacts and the bypass diodes are shown as if they were located in a same cross-section, but in practice this may not be so.

FIG. 6 shows the first photo-voltaic cells 10a,b and bypass diodes 60 of the series connections of successive first and second sub-matrices. The other photo-voltaic cells in the series connections are not shown. In this embodiment the bypass diode 60 of each sub-matrix has terminals connected to a respective first area 62a of electrically conductive material on the foil 20 and an auxiliary contact of a first photo-voltaic cell 10a in the series connection of the sub-matrix. First area 62a connects to a contact 66 to the first photo-voltaic cell 10b in the series connection of the next sub-matrix. This first photo-voltaic cell 10b in the series connection of the next sub-matrix similarly has an auxiliary contact, a bypass diode 60 being connected between the auxiliary contact and the foil. Conductors on each of the first photo-voltaic cells 10a connect the auxiliary contacts to a normal contact of the cell, which serves for collecting current from the first of a first photo-voltaic cell 10a.

This normal contact of the first photo-voltaic cells 10a in the first sub-matrix is connected to a second area 62b of electrically conductive material on the foil 20, which serves as connection to the normal contact of a further cell (not shown) in the series connection of the first sub-matrix. Apart from connecting the bypass diode 60 to the first photo-voltaic cell 10b in the series connection of the second sub-matrix, the first area 62a connects to a normal contact 64 of the last photo-voltaic cell (not shown) in the series connection of the first sub-matrix.

Thus the bypass circuit of this sub-matrix runs from second area 62b, through the connection from second area 62b to the contact on the first photo-voltaic cell 10a, then via a conductor on the first photo-voltaic cell 10a to the bypass diode 60, from there to first area 62a and to the contacts 64, 66 of the second and third photo-voltaic cell. Preferably, the contact to bypass diode 60 on first photo-voltaic cell 10a is adjacent to the contact from that cell to second area 62b. The figure shows the contacts and the diode 60 in one cross-section to illustrate the connections, but again it is emphasized that in practice the diodes and the contacts need not be in the same cross-section. Connection of bypass diode 60 between an area 62b of electrically conductive material on the foil 20 and a contact to a cell 10a may simplify manufacturing by relaxing location tolerance for bypass diode 60. For example, the bypass diode may be mounted on the first area 62b before the cells and the foil are connected. In embodiment, the bypass diodes of all sub-matrices may be connected in a similar way.

Although examples have been shown wherein all photo-voltaic cells in the matrix are rectangular, it should be noted that alternatively non-rectangular cells may be used.

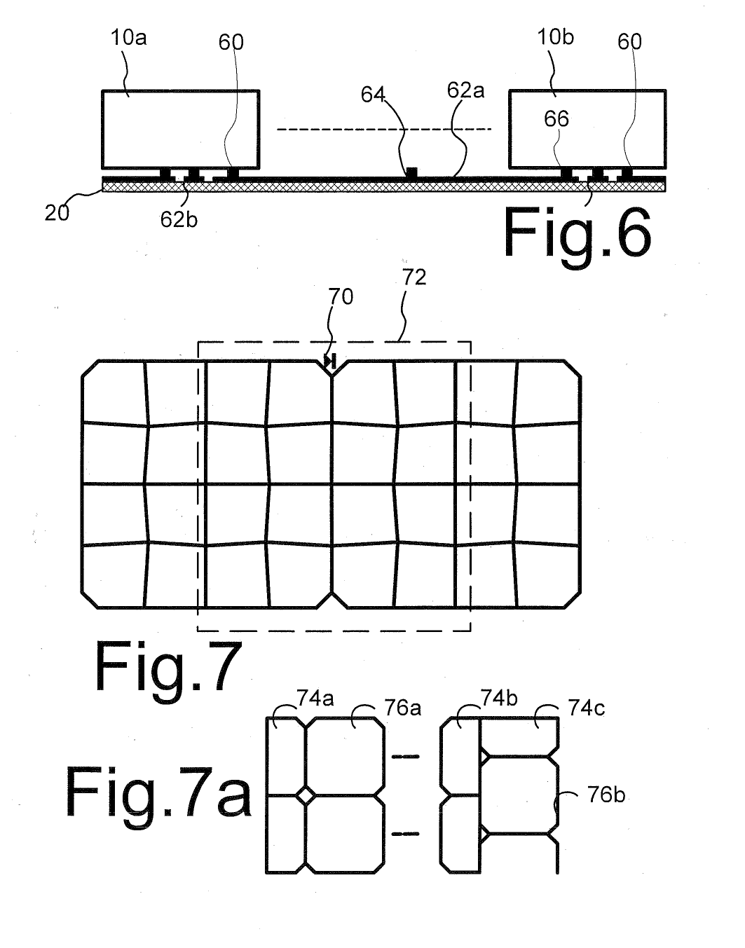

FIG. 7 shows an example of a portion of a matrix wherein non-rectangular cells are used. All cells have the same area, which optimizes output. 4 row×4 column sub-arrangements of cells can be distinguished. Cells at the corners of the sub-arrangements (e.g. from the corners of an array on a wafer) have beveled corners. To achieve a sub-arrangement of rows and columns with equal area cells in this case, non-rectangular cells are used. Measured edge to edge, the cells at the corners are wider and higher on average than the other cells in the same edge row or column in the sub-arrangement, to compensate the area lost to the beveled corners. In turn the other cells in the edge rows are higher on average than non-edge cells and other cells in the edge rows are wider on average than non-edge cells to compensate for area lost to corner cells. The cells may be formed for example by first cutting a wafer with beveled corners along straight lines into four quadrants, and then cutting the quadrants along four lines from the edges that converge at an interior point with coordinates selected to make the four cut parts of the quadrant equal in area, compensating for the lack at the corner due to beveling.

A sub-matrix 72 is formed from cells of a pair of adjacent sub arrangements. In this way, the space left at the beveled corners is available for locating the bypass diode 70 for the sub-matrix. The cells in the sub-matrix may be interconnected as described before.

FIG. 7a shows configuration of sub-arrangements 74a-c. 76a,b of cells in the top two rows of the matrix (the individual cells are not shown). At the left of each row a half sub-arrangement 74a of tow cells wide in the horizontal direction is used, with the beveled corners on the right, i.e after two columns of cells. Next to the right, each row contains a number of full sub-arrangements 76a is used, followed by a half sub-arrangement 74b of two cells wide, with the beveled corners on the left. Along the rows the sub-matrices are formed each time from cells from each time two cells wide, taken from full sub-arrangements, expect at the sides. In the final four columns a similar arrangement as in the rows is used, but rotated by ninety degrees. First a half sub-arrangement 74c, with beveled corners on the lower side, followed downward by a number of full sub-arrangements 76b. In this way space is created for locating the bypass diodes between the cells with beveled corners.

Although examples have been shown wherein all photo-voltaic cells in the matrix have the same orientation, it should be appreciated that instead the cells may have different orientations, e.g. with some cells having orientations that are an integer multiple of ninety degrees rotated relative to other cells. This may be used for example to simplify the layout of the electrically conductive material on the foil. For example, the photo-voltaic cells in the sub-matrices in the rightmost column may have orientations rotated by ninety degrees with respect to the other cells. In this case, similar layouts may be used in all sub-matrices. However, it is preferred to use a matrix of photo-voltaic cells with identical orientations, because this simplifies manufacture.

Although examples have been shown for specific numbers of rows and columns of cells in the overall matrix as well as for sub-matrices with specific numbers of rows and columns P, it should be appreciated that other numbers may be used. P=4 cells in a 4×4 sub-matrix is preferred, as it provides an effective way of reducing the effect of shadows. Of course, the roles columns and rows may be interchanged, as well as the roles of left-right and top-bottom.

Although a connection pattern has been shown that runs through substantially an entire row of sub-matrices and turns at the rightmost matrix, it should be understood that the pattern may turn at any point along the row, sub-matrices of the type shown in FIG. 5a,b being provided there. For example, the described matrix may be part of a larger matrix wherein the described matrix forms a part with sub-matrices of the type shown in FIG. 5a,b at the edge of the described matrix. Similarly, a larger number than two of series connected sub-matrices of the type shown in FIG. 5a,b may be used to connect rows that are not adjacent. In fact, an arbitrary pattern of connection through the matrix of sub-matrices can be realized. As another example, a first and second row of first sub-matrices that are connected by second sub-matrices may lie separated by further first and/or second sub-matrices. In this case the first and second row need not be mirror images of each other. However, it is preferred to use patterns that run through full rows and successively through adjacent rows, as this provides an easy way of limiting voltage differences between adjacent cells.

Although an embodiment with electrical connections by means of a flexible foil with areas of electrically conductive material has been shown, it should be appreciated that instead other connection structures may be used, for example a stiff insulating layer with areas of electrically conductive material.

1. An assembly of photo-voltaic cells, comprising
photo-voltaic cells arranged in a matrix with rows and columns of photo-voltaic cells,
an electrical connection structure providing a series connection of the photo-voltaic cells of the matrix, and
bypass diodes, each bypass diode connected in parallel with the photo-voltaic cells of a respective part of the series connection, wherein the electrical connection structure comprises
rows of first sub-matrix connection patterns, each first sub-matrix connection pattern providing one of the respective parts of the series connection, extending over a plurality of rows of photo-voltaic cells of the matrix, running back and forth along successive columns through the plurality of rows;
second sub-matrix connection patterns, connecting the first sub-matrix connection patterns at ends of a pair of the rows of first sub-matrix connection patterns, each second sub-matrix connection pattern providing a further one of the respective parts of the series connection, extending over a plurality of columns of photo-voltaic cells of the matrix, running back and forth along successive rows through the plurality of columns.

2. An assembly according to claim 1, wherein said pair lies between further ones of the rows of the first sub-matrix connection patterns located adjacent the rows in said pair, wherein the first sub-matrix connection patterns at further ends of the rows in the pair, opposite said ends where the second sub-matrix connection patterns connect the rows of the pair, are connected directly to adjacent first sub-matrix connection patterns in the further ones of the rows.

3. An assembly according to claim 1, wherein the rows in the pair are adjacent to each other, the electrical connection structure comprising
a plurality of such pairs of adjacent rows of first sub-matrix connection patterns,
a column of the second sub-matrix connection patterns, connecting the first sub-matrix connection patterns within the pairs and
direct connections between the first sub-matrix connection patterns of adjacent rows from successive ones of the pairs at further ends of the rows opposite said ends where the second sub-matrix connection patterns connect the first sub-matrix connection patterns.

4. An assembly according to claim 1, wherein, in each row of the pair, the first sub-matrix connection pattern at said end connects the second sub-matrix connection pattern in series to a photo-voltaic cell at a first corner of a sub-matrix of photo-voltaic cells that are connected by said part of the series connection that is provided by the first sub-matrix connection pattern, the first corners in each row of the pair lying away from the other row of the pair, with intermediate photo-voltaic cells between the photo-voltaic cell at the first corners.

5. An assembly according to claim 1, wherein the first sub-matrix connection patterns at the ends of the pair of the rows each run back and forth through a first number P of rows, and the second sub-matrix connection patterns each run said first number P times back and forth through the plurality of columns.

6. An assembly according to claim 5, wherein the first sub-matrix connection patterns at the ends of the pair of the rows each run a second number Q times back and forth through said first number P of rows, and the second sub-matrix connection patterns each run said first number P times back and forth through said second number Q of columns.

7. An assembly according to claim 6, wherein the first number P and the second number Q are equal.

8. An assembly according to claim 1, wherein the bypass diodes are located at edges of the first and second sub-matrix connection patterns.

9. An assembly according to claim 1, wherein all photo-voltaic cells are arranged having identical orientations in the matrix, the first sub-matrix connection pattern having identical layouts, the second sub-matrix connection pattern having layouts that differ from that of the first sub-matrix connection pattern.

10. An assembly according to claim 1, wherein each of the first and second sub-matrix connection patterns comprises a first and second one of the photo-voltaic cells at the ends of the respective part of the series connection that is provided by the sub-matrix connection pattern, the first and second one of the photo-voltaic cells being located along a straight edge of the sub-matrix connection pattern, the electrical connection structure in the sub-matrix connection pattern comprising a pair of areas of electrically conducting material extending along said edge, electrically connected to contacts of the first and second one of the photo-voltaic cells respectively, the bypass diode that is connected in parallel with the photo-voltaic cells of the respective part of the series connection being located at said edge, electrically connected between the pair of areas.

11. An assembly according to claim 1, wherein each of the first and second sub-matrix connection patterns comprises a first and second one of the photo-voltaic cells at the ends of the respective part of the series connection that is provided by the sub-matrix connection pattern, the electrical connection structure in the sub-matrix connection pattern comprising a first and second areas of electrically conducting material, electrically connected to contacts of the first and second one of the photo-voltaic cells respectively, the bypass diode that is connected in parallel with the photo-voltaic cells of the respective part of the series connection being located sandwiched between a further contact of the first one of the photo-voltaic cells and the second area of electrically conducting material.

12. An assembly according to claim 1, wherein at least one first sub-matrix comprises a pair of cells from the matrix that have beveled corners adjacent each other, leaving a space between the beveled corners of the cells in that pair, the bypass diode of said at least one first sub-matrix being located in said space.

13. An assembly according to claim 12, wherein the cells of said pair are located at the corners of respective quadrants of said at least one first sub-matrix, each of said quadrants comprising a respective sub-set of the cells of the matrix, the directions of edges of the cells in the quadrant deviating from the row and column direction to equalize the areas of the cells in the quadrant, compensating for area reduction due to the beveled corner.

14. An assembly according to claim 1, wherein the photo-voltaic cells are back contact cells, each photo-voltaic cell having back surface that contains contacts to base and emitter areas of the cell respectively.

15. A method of manufacturing an assembly of photo-voltaic cells, the method comprising
providing an electrical connection structure that provides for a series connection of the photo-voltaic cells,
providing bypass diodes on said electrical connection structure, each bypass diode for connection in parallel with the photo-voltaic cells of a respective part of the series connection;
arranging the photo-voltaic cells in a matrix with rows and columns of photo-voltaic cells;
establishing electrical contact between contacts of the photovoltaic cells and the electrical connection structure, wherein the electrical connection structure comprises
rows of first sub-matrix connection patterns, each first sub-matrix connection pattern providing one of the respective parts of the series connection, extending over a plurality of rows of photo-voltaic cells of the matrix, running back and forth along successive columns through the plurality of rows;
second sub-matrix connection patterns, connecting the first sub-matrix connection patterns at ends of a pair of the rows of first sub-matrix connection patterns, each second sub-matrix connection pattern providing a further one of the respective parts of the series connection, extending over a plurality of columns of photo-voltaic cells of the matrix, running back and forth along successive rows through the plurality of columns.

16. A method according to claim 15, comprising using photo-voltaic cells cut from wafers, and arranging the cells cut from the wafers in said step of arranging the photo-voltaic cells in the matrix with rows and columns of photo-voltaic cells.
